(19) United States
(12) Patent Application Publication
(10) Pub. No.: US 2022/0099100 A1
(43) Pub. Date: Mar. 31, 2022

(54) IDENTIFICATION SIGNALS FOR FANS

(71) Applicant: Hewlett-Packard Development Company, L.P., Spring, TX (US)

(72) Inventors: Roger A. Pearson, Fort Collins, CO (US); Andrew L. Wiltzius, Fort Collins, CO (US)

(73) Assignee: Hewlett-Packard Development Company, L.P., Spring, TX (US)

(21) Appl. No.: 17/415,005

(22) PCT Filed: May 22, 2019
(86) PCT No.: PCT/US2019/033438

§ 371 Date: Jun. 17, 2021

(51) Int. Cl. F04D 27/00; H02P 27/08; H05K 7/20

(52) U.S. Cl. CPC F04D 27/004; H05K 7/20209; H02P 27/08

(57) ABSTRACT

An example of an apparatus may include an input connection to receive a pulse-width-modulated signal. The pulse-width-modulated signal may control a speed of a fan. An output connection may provide a tachometer signal to indicate the speed of the fan. A controller may provide an identification signal via the output connection. The identification signal may be provided in response to receipt of a predetermined duty cycle via the pulse-width-modulated signal. The identification signal may provide an identification corresponding to the fan.

### BACKGROUND

Fans may be used to assist in cooling systems. The fans may increase airflow and be used in conjunction with heat sinks or other heat dissipation devices. Four-wire fans may include power and ground connections, a connection to control the speed of the fan, and a connection to indicate the speed of the fan.

### BRIEF DESCRIPTION OF THE DRAWINGS

Various examples will be described below referring to the following figures:

FIG. 1 shows an apparatus including a controller, an input connection, and an output connection in accordance with various examples;

FIG. 2 shows an apparatus including a fan, an input connection, and an output connection in accordance with various examples;

FIG. 3 shows an apparatus including a controller, a fan, and a switch in accordance with various examples;

FIG. 4 shows an example method to determine if a duty cycle of a signal is below a predetermined duty cycle and provide an identification signal in response to the determination; and

FIG. 5 shows an example method to determine duty cycles of a signal and to provide an identification signal in response to one determination and a tachometer signal in response to another determination.

### DETAILED DESCRIPTION

Fans come in many different varieties. Even fans of the same general size and shape may have different fan speeds and capabilities. Fans may be replaceable, and the system may be optimized differently based on what types of fans are present in various fan slots. Automating the identification of different fans in a system may enable identification of an incorrect fan installation or provide an ability to optimize the system based on the fans present.

The tachometer signal of a four-wire fan may be used to provide an identification of the fan. The frequency of the tachometer signal indicates the rotational speed of the fan. The duty cycle of the tachometer signal may be modified to provide an identification of the fan when a certain signal is received over the fan speed control connection, such as a signal to stop the fan.

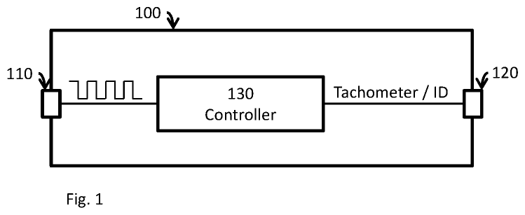

FIG. 1 shows an apparatus 100 including a controller 130, an input connection 110, and an output connection 120 in accordance with various examples. The controller 130 is coupled to the input connection 110. The input connection 110 is to receive a pulse-width-modulated (PWM) signal to control a fan speed of a fan. The controller 130 is coupled to the output connection 120. The output connection is to provide a tachometer signal or an identification signal. The tachometer signal indicates the fan speed of the fan. The identification signal provides an identification corresponding to the fan.

In various examples, the PWM signal may be a periodic signal, such as a square wave or pulse train. The PWM signal may control the fan based on the duty cycle of the PWM signal. The duty cycle represents a percentage of the period in which the signal is high versus low. A 50% duty cycle indicates that half the time the signal is high. A 25% duty cycle indicates that the signal is high a quarter of the time. A 100% duty cycle may indicate the signal is a fixed high signal. A 0% duty cycle may indicate the signal is a fixed low signal. A higher duty cycle may indicate the fan is to rotate at a higher speed. A duty cycle of 100% may indicate the fan is to rotate at its highest speed. A duty cycle of 0% may indicate the fan is to stop rotating, turn off, or to run at its lowest possible speed. For various fans, the operation at a 100% duty cycle or 0% duty cycle may not be defined. If the PWM signal is maintained at a certain frequency, the duty cycle of the PWM signal corresponds to a pulse width of the signal. A pulse width or duty cycle may be used to request the identification signal be provided via the output connection 120. If a pulse width is used, the pulse width used to specify an identification request may vary based on the frequency.

The controller 130 may determine the duty cycle of the PWM signal provided via the input connection 110. In various examples, a low-pass filter may be used to convert the PWM signal into a direct current (DC) voltage value. An analog to digital converter, such as a voltage comparator, may be used to convert the DC voltage value into a number representing the duty cycle. For example, if the PWM signal varies between 0 volts (V) and 5 V, filtering a 50% duty cycle PWM signal may produce a DC voltage of 2.5 V, while filtering an 80% duty cycle may produce a DC voltage of 4.0 V. The controller may compare the filtered PWM signal against a reference voltage that corresponds to a predetermined pulse width or duty cycle. A duty cycle or pulse width may be determined by sampling the PWM signal to determine how long it is high or low.

Based on the PWM signal, the controller 130 causes a tachometer signal or an identification signal to be output via the output connection 120. In various examples, the frequency of the tachometer signal indicates a speed of the fan. The tachometer may have two pulses per blade revolution, though this may vary across fans. The identification signal may include an identification indicated by a DC high voltage level, a DC low voltage level, or a pulse wave.

In various examples, a PWM signal with a duty cycle of 0% may be used as a predetermined signal for the controller 130 to provide an identification signal via the output connection 120. A PWM signal with a duty cycle of 0% may indicate that the fan is to output an identifier. When the controller 130 detects a non-0% duty cycle on the PWM signal, the controller 130 causes the tachometer signal to be provided via the output connection 120. When the controller 130 detects a 0% duty cycle on the PWM signal, the controller 130 causes the identification signal to be provided via the output connection 120.

In various examples, the predetermined duty cycle used by the controller 130 to send the tachometer signal or the identification signal may be a value other than 0%. The controller 130 may use a small duty cycle to account for potential noise on the input connection 110 line or to handle corner case issues. A duty cycle slightly larger than 0%, such as 0.5%, may be used to request an identification signal on the output connection 120. In such a case, the controller 130 would cause the identification signal to be provided if the duty cycle of the PWM signal falls below 0.5%, and otherwise would cause the tachometer signal to be provided. Different over-under values may be used to prevent the controller 130 from quickly swapping back and forth between the tachometer signal and the identification signal. The controller 130 may start providing the identification signal if the duty cycle falls below 0.5%, but not resume providing the tachometer signal until the duty cycle exceeds 1%. The controller 130 may provide the identification signal for a minimum duration of time or cycles before switching to the tachometer signal.

In various examples, the controller 130 may provide the identification signal if the duty cycle exceeds a predetermined value. For some systems, a fan may be intended to operate at low speeds. Receiving a PWM signal with a high duty cycle may indicate that the identification signal is to be provided over the output connection 120. The controller 130 may limit the fan to a capped speed based on the predetermined value used to specify an identification request.

The identification signal may be expressed in different formats. The format used may be based on the specifications of the fans and how they are to be used in a system.

In various examples, the identification signal may be a DC high value to indicate one type of fan and a DC low value to indicate a second type of fan. This may be used when the surrounding circuitry monitors the output connection 120 to make sure the fan stops when the input connection 110 provides a PWM signal with a 0% duty cycle. As the tachometer signal in such cases may validly be a DC high value or a DC low value, providing an identification signal with a DC high value or a DC low value may not disturb an existing system. But a first type of fan may provide a DC high signal as an identification, while a second type of fan may provide a DC low value as an identification. An additional control unit in the surrounding system may monitor the output connection 120 and determine whether a fan is of the first type or the second type, based on whether a DC high or DC low value is output when a PWM signal with a 0% duty cycle is provided to the input connection 110.

In various examples, in systems that monitor the output connection 120 when providing a PWM signal of 0% duty cycle on the input connection 110, additional fan types may be identified through use of a low-frequency signal. A low-frequency signal may indicate the fan is revolving at a low speed, or it may indicate the fan is slowly oscillating in place between sensor positions used to measure the fan speed. Such a low-frequency signal may not disturb existing systems that monitor the output connection 120, but may be able to provide a third identification or even more identifications of fan types. For example, if a frequency of 1 hertz (Hz) is sufficiently low as to not disturb an existing system, a frequency of 1 Hz may identify a third type of fan. To identify more than three fan types, the frequency on the output connection 120 may be modified. A frequency of 1 Hz may identify a third fan type, while a frequency of 0.5 Hz may identify a fourth fan type. The number of fan types that may be thus identified may depend on the accuracy of the frequency generation, frequency measurements by the surrounding system, and the amount of time that can be allotted for the identification once the PWM signal requests fan identification.

In various examples, fan identification information may be encoded in the duty cycle of the signal. If a 1 Hz signal is used, the DC high value may indicate a first fan, the DC low value may indicate a second fan, a 50% duty cycle may indicate a third fan, and other fan identifications may be indicated by other duty cycles, such as 25% and 75%. The number of different duty cycles that may be used to identify different fans may depend on the accuracy of the signal generation and measurement equipment to be used.

In various examples, a combination of duty cycle and frequency may also be used to identify different types of fans. For example, 1 Hz at 25% duty cycle may identify one fan, while 0.5 Hz at 50% duty cycle may identify a second fan.

In various examples, providing a pulsed signal via the output connection 120 may not be an issue when the PWM signal received over the input connection 110 has a 0% duty cycle. As the PWM signal may indicate the fan is to be stopped, the surrounding system may not monitor the output connection 120 in such circumstances. The identification signal provided by the output connection 120 may use a wider range of frequencies to identify different fan types. For example, a frequency less than 1 Hz may indicate one fan type, a frequency between 1 Hz and 5 Hz may indicate a second fan type. The frequencies used may extend into high frequency ranges, depending on the signal generation and measuring equipment to be used.

In various examples, the identification signal may include an encoded signal, such as providing a serial encoding of binary-coded decimal. The identification signal may modify the duty cycle of a square wave to indicate a binary 1 or 0. A duty cycle of 50% may be used to indicate a start or a stop bit. A duty cycle of 25% may be used to indicate a binary 0, and a duty cycle of 75% may be used to indicate a binary 1. The identification signal may repeat. Using a start or stop bit may allow the identification signal to include an identification number encoded in an arbitrary number of bits. Thus, one identification signal may use one start/stop bit and 4 numeric bits, while another identification signal may use one start/stop bit and 17 numeric bits. The start/stop bit may also enable the identification signal to leave off leading zeroes. The identification signal may modify the duty cycle of the square wave with successive pulses.

In various examples, a base-3 or other encoding system may be used. For example, in a base-3 system, a 20% duty cycle may indicate a start/stop bit, a 40% duty cycle may indicate a trinary 0, a 60% duty cycle may indicate a trinary 1, and an 80% duty cycle may indicate a trinary 2.

In various examples, the apparatus 100 may be used in conjunction with a fan. The apparatus 100 may be placed between the fan and surrounding circuitry. In addition to being used by the controller 130, the PWM signal received by the input connection 110 may be provided to the fan in parallel or passed through the apparatus 100 via another output connection, if the apparatus 100 is meant to be used in-line with the fan. The apparatus 100 may include another input connection to receive the tachometer signal, which the controller 130 may then multiplex with the identification signal to be output via the output connection 120.

The apparatus 100 may be used to provide expanded functionality to existing four-wire fans. Using the existing PWM and tachometer signals, the apparatus 100 may provide an identification signal when certain PWM signals are received. Additional logic in the surrounding circuitry may control when the PWM signal to request fan identification is provided via the input connection 110 and to interpret the reply via the output connection 120. When used in-line with the fan as a separate device, the apparatus 100 may provide an arbitrary identification for the fan. In this way, the installer or owner of the system could assign an identification to a particular fan or type of fan. As an in-line device, the apparatus 100 may be mixed and matched with various fans at different times.

In various examples, the apparatus 100 may include a multiplexor, switch, or comparable circuitry to allow the controller 130 to select between the tachometer signal and the identification signal. The output of the multiplexor or switch may be coupled to the output connection 120.

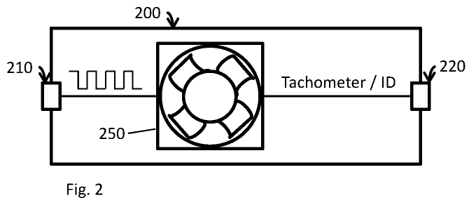

FIG. 2 shows an apparatus 200 including a fan 250, an input connection 210, and an output connection 220 in accordance with various examples. The fan 250 may include a controller to determine when to send its tachometer signal or its identification signal via the output connection 220. The fan 250 may send the tachometer signal while the fan is being controlled to operate at certain speeds. The fan 250 may send the identification signal while the fan receives a request for the identification signal via the input connection 210. The request for the identification signal may be a pulse-wave-modulated signal that is above or below a certain duty cycle.

Including the fan 250 in the apparatus 200 may enable the identification of the fan to be set at the time of manufacture. A manufacturer may set the identification signal to indicate a model number of the apparatus 200. A manufacturer may set the identification signal to be a globally unique identifier (GUID) to identify the specific apparatus 200, or a combination of a model number and GUID.

In various examples the identification signal may be programmable. The apparatus 200 may include a memory to store an identifier. The apparatus 200 may base the identification signal on the identifier. The apparatus 200 may include a port to allow reprogramming of the identifier.

In various examples, the identifier may be controlled by a selector. A selector in the apparatus 200 may allow a user to modify the identification signal. For example, a slider switch may have four different positions, used to select between four identification signals. This may allow a user to modify the identification of the apparatus 200.

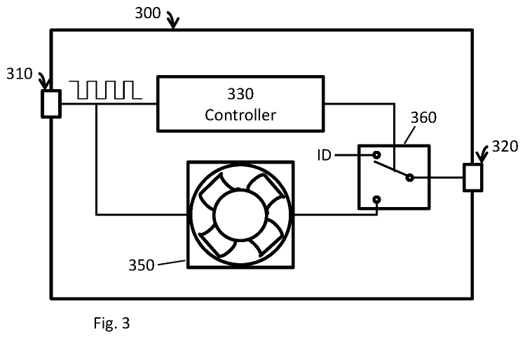

FIG. 3 shows an apparatus 300 including a controller 330, a fan 350, and a switch 360 in accordance with various examples. The apparatus 300 includes an input connection 310 and an output connection 320. The input connection 310 may receive a PWM signal to control the speed of the fan 350. The output connection 320 may provide a tachometer signal or an identification signal, based on the PWM signal. The fan 350 may provide a tachometer signal to the switch 360. The tachometer signal may be based on a rotary encoder, magnetic windings of the fan, or other feedback mechanism to indicate the fan speed. The identification signal may also be coupled to the switch 360. The identification signal may be generated by the controller 330 or other circuitry in the apparatus 300. The controller 330 is coupled to the switch 360 to select between providing the identification signal or the tachometer signal to the output connection 320.

In various examples, the tachometer signal may be supplied to the controller 330. The controller 330 may output a signal to the output connection 320 indicative of the tachometer signal or the identification signal.

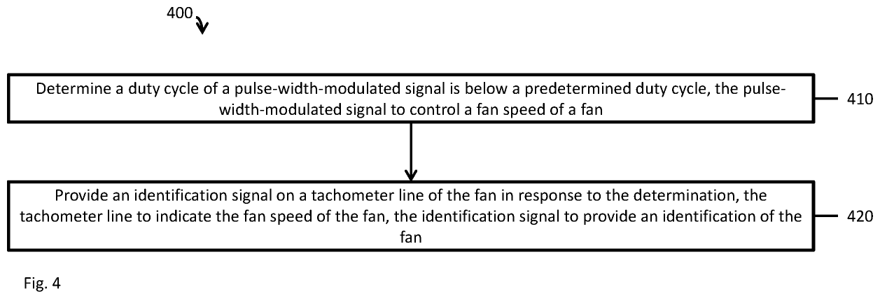

FIG. 4 shows an example method 400 to determine if a duty cycle of a signal is below a predetermined duty cycle and provide an identification signal in response to the determination. Method 400 includes determining a duty cycle of a pulse-width-modulated signal is below a predetermined duty cycle, the pulse-width-modulated signal to control a fan speed of a fan (410). Method 400 includes providing an identification signal on a tachometer line of the fan in response to the determination, the tachometer line to indicate the fan speed of the fan, the identification signal to provide an identification of the fan (420).

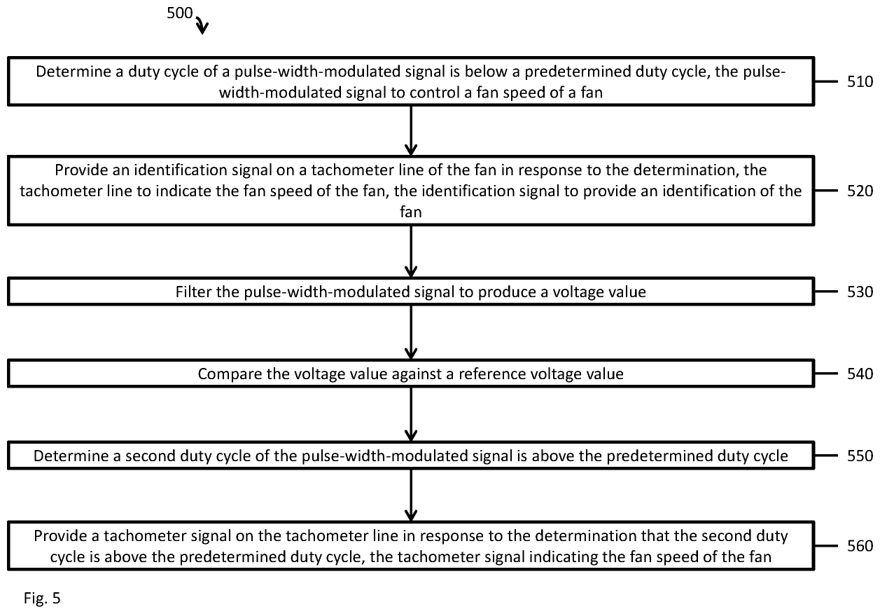

FIG. 5 shows an example method 500 to determine duty cycles of a signal and to provide an identification signal in response to one determination and a tachometer signal in response to another determination. Method 500 includes determining a duty cycle of a pulse-width-modulated signal is below a predetermined duty cycle, the pulse-width-modulated signal to control a fan speed of a fan (510). Method 500 includes providing an identification signal on a tachometer line of the fan in response to the determination, the tachometer line to indicate the fan speed of the fan, the identification signal to provide an identification of the fan (520). Method 500 includes filtering the pulse-width-modulated signal to produce a voltage value (530). Method 500 includes comparing the voltage value against a reference voltage value (540). Method 500 includes determining a second duty cycle of the pulse-width-modulated signal is above the predetermined duty cycle (550). Method 500 includes providing a tachometer signal on the tachometer line in response to the determination that the second duty cycle is above the predetermined duty cycle, the tachometer signal indicating the fan speed of the fan (560).

In various examples, the tachometer signal may be a pulse train, where the frequency of the pulse train corresponds to the fan speed. The pulse train may be generated by rotation of the fan blades. For example, a magnet may be placed near the base of a fan blade and a sensor located at a corresponding location in the frame of the fan. When the magnet is adjacent the sensor, a voltage high signal may be provided. When the magnet is non-adjacent to the sensor, a voltage low signal may be provided. One rotation of the fan blade may thus cause a single pulse of the pulse train to be generated. Other ways of generating the pulse train may be used.

In various examples, the identification signal encodes the identification of the fan in its duty cycle. This may be done by providing a pulse-width-modulated signal, such as a pulse train. Interpreting the identification signal may include use of a low-pass filter to convert the pulse train into a DC voltage value. The DC voltage value may then be compared against a reference voltage value to determine the identification of the fan. Multiple reference voltage values may be used to determine a voltage range of the DC voltage value, with different voltage ranges representing different identifications.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An apparatus comprising:
an input connection to receive a pulse-width-modulated signal, the pulse-width-modulated signal to control a fan speed of a fan;
an output connection to provide a tachometer signal, the tachometer signal to indicate the fan speed of the fan; and
a controller coupled to the input connection and the output connection, wherein the controller is to provide an identification signal via the output connection in response to the receipt of a predetermined duty cycle via the pulse-width-modulated signal, the identification signal to provide an identification corresponding to the fan.

2. The apparatus of claim 1, wherein the identification signal includes a pulse wave signal, the frequency of the pulse wave signal based on the identification.

3. The apparatus of claim 1, wherein the identification signal includes a binary signal, the bits encoded in a duty cycle of the identification signal.

4. The apparatus of claim 1 comprising:
an input tachometer connection to receive the tachometer signal from the fan; and
a switch coupled to the input tachometer connection, the output connection, and the controller, the controller to cause the switch to provide either the tachometer signal or the identification signal to the output connection.

5. The apparatus of claim 4, wherein the controller is to:
determine that the pulse width modulated signal includes a duty cycle below a predetermined duty cycle; and
cause the switch to provide the identification signal to the output connection in response to the determination.

6. An apparatus comprising:
a fan;
an input connection coupled to the fan, the input connection to receive a fan speed control signal, the fan speed control signal comprising a pulse train, a speed of the fan to be controlled based on a duty cycle of the pulse train; and
an output connection coupled to the fan, the output connection to provide an identification signal when the duty cycle is less than a predetermined duty cycle, the identification signal to provide an identification of the fan, and the output connection to provide a tachometer signal when the duty cycle is greater than the predetermined duty cycle, the tachometer signal to indicate the speed of the fan.

7. The apparatus of claim 6 comprising a controller, wherein the controller is to compare the duty cycle with the predetermined duty cycle.

8. The apparatus of claim 7 comprising a switch coupled to the output connection and the controller, the controller to control the switch based on the comparison, the switch to select between the identification signal and the tachometer signal.

9. The apparatus of claim 6, the identification signal comprising a voltage high signal, a voltage low signal, or a pulse train.

10. The apparatus of claim 6 comprising an identification signal selector to control whether the identification signal comprises a voltage high signal, a voltage low signal, or a pulse train.

11. A method comprising:
determining a duty cycle of a pulse-width-modulated signal is below a predetermined duty cycle, the pulse-width-modulated signal to control a fan speed of a fan; and
providing an identification signal on a tachometer line of the fan in response to the determination, the tachometer line to indicate the fan speed of the fan, the identification signal to provide an identification of the fan.

12. The method of claim 11 comprising:
determining a second duty cycle of the pulse-width-modulated signal is above the predetermined duty cycle; and
providing a tachometer signal on the tachometer line in response to the determination that the second duty cycle is above the predetermined duty cycle, the tachometer signal indicating the fan speed of the fan.

13. The method of claim 12, wherein the tachometer signal includes a pulse train, and a frequency of the pulse train corresponds to the fan speed.

14. The method of claim 11, wherein the determining includes:
filtering the pulse-width-modulated signal to produce a voltage value; and
comparing the voltage value against a reference voltage value.

15. The method of claim 11 comprising:
receiving a tachometer signal from the fan; and
selecting between providing the tachometer signal and providing the identification signal on the tachometer line based on the duty cycle of the pulse-width-modulated signal.
